(19) United States
(12) Patent Application Publication
(10) Pub. No.: US 2026/0010668 A1
(43) Pub. Date: Jan. 8, 2026

(54) DRONE OPERATION WITH MULTIPLE FLIGHT SIMULATORS

(71) Applicant: Airtonomy, Inc., Grand Forks, ND (US)

(72) Inventor: Ahmed Atef Abbas Elsaharti, Grand Forks, ND (US)

(21) Appl. No.: 18/763,007

(22) Filed: Jul. 3, 2024

(51) Int. Cl. G06F 30/17

(52) U.S. Cl. CPC G06F 30/17

(57) ABSTRACT

The techniques presented relate to a simulation system that integrates a Drone Custom Simulator (DCS), which emulates native autopilot logic and physics, with a Universal Open Simulator (UOS), to provide a comprehensive virtual drone flight environment. The solution includes a software-based bridge to facilitate information exchange between the DCS and the UOS, enabling the simulation of external sensors and the creation of custom environments. The DCS offers a basic simulation for training and testing purposes, while the UOS provides a platform for designing complex scenarios with complex environments and sensor simulations. This simulation environment is beneficial for pilots, developers, and testers, allowing them to safely and effectively test drone behavior, control programs, and software algorithms in a controlled virtual space that closely mirrors real-world conditions. The system provides for the testing of manual and autonomous flight, with the option to transition seamlessly to real-world drone operation after testing is completed.

### TECHNICAL FIELD

The subject matter disclosed herein generally relates to methods, systems, and machine-readable storage media for providing flight simulation tools for drone operations.

### BACKGROUND

Drone operators may have to operate drones under challenging environments, so testing on simulators is important to gain expertise when flying difficult missions, especially for novice operators who are learning the system. Additionally, some programs are created to control drones, but testing these programs in real-world environments can be expensive and dangerous. Therefore, it is important to provide testing environments for the programmatic control of drones.

Some drone manufacturers provide their own simulators created specifically for a particular drone. However, these custom simulators may have only limited features and lack other powerful features that other open-source simulators provide, such as the use of cameras in the drone and other types of sensors.

Drone operators often encounter limitations due to the lack of access to various components within the drone platform. The vendor simulator may provide a simplistic environment where users can simulate drone flight without actually activating the drone propellers or causing any harm. This limitation impacts developers and engineers who require more intricate tasks, such as developing algorithms for navigating between obstacles or practicing flying maneuvers through a set of buildings. The drone simulator may not be sufficient for these advanced requirements, as it lacks the capability to allow users to position objects within the simulation environment. Additionally, the drone simulator may not support certain sensors like lidar (Light Detection and Ranging), which are essential for tasks such as wind turbine inspection.

The lack of support for integrating lidar data and other sensors in the drone simulator poses a significant obstacle for developers looking to create advanced algorithms and test them in a simulated environment. This limitation highlights the need for more comprehensive simulation tools that can accommodate a broader range of scenarios and sensor integrations.

### BRIEF DESCRIPTION OF THE DRAWINGS

Various appended drawings illustrate examples of the present disclosure and cannot be considered limiting its scope.

FIG. 1 is a diagram illustrating a sample system for inspecting assets using an autonomous drone.

FIG. 2 is a flowchart of a method for drone data management, according to some example embodiments.

FIG. 3 illustrates a sample drone simulation environment.

FIG. 4 is a flowchart of a method for navigating a drone in a customized simulation environment, according to some examples.

FIGS. 5A-5B show virtual images obtained during a simulation flight, according to some examples.

FIG. 6 is an image provided by one simulator during flight, according to some examples.

FIG. 7 is a flowchart of a method for simulator bridge operations, according to some examples.

FIG. 8 illustrates a sample architecture for implementing example embodiments.

FIG. 9 is a flowchart of a method for providing a customized simulation environment for navigating and testing a virtual drone, according to some examples.

FIG. 10 is a block diagram illustrating an example of a machine upon or by which one or more example process examples described herein may be implemented or controlled.

### DETAILED DESCRIPTION

Example methods, systems, and computer programs are directed at providing a customized simulation environment for navigating and testing a virtual drone. Examples merely typify possible variations. Unless explicitly stated otherwise, components and functions are optional and may be combined or subdivided, and operations may vary in sequence or be combined or subdivided. The following description provides numerous specific details to provide a thorough understanding of examples. However, it will be evident to one skilled in the art that the present subject matter may be practiced without these specific details.

The proposed methodology aims to empower both pilots and developers by allowing them to navigate a particular drone manually or programmatically within a customized simulated environment that includes the use of a Drone Custom Simulator (DCS) and powerful Universal Open Simulator (UOS). Techniques are presented to create this custom simulation environment by integrating the features of the DCS in the UOS. This environment provides simulated sensor data and imagery that accurately represents the conditions of the scenario around the drone’s motion and actions. Importantly, since the actual autopilot of the drone is still being used, the autopilot behavior within the simulation reflects the native behavior of the drone, ensuring a realistic simulation similar to actual flight scenarios.

The techniques presented relate to a simulation system that integrates a Drone Custom Simulator (DCS), which emulates native autopilot logic and physics, with a Universal Open Simulator (UOS), to provide a comprehensive virtual drone flight environment. The solution includes a software-based bridge to facilitate information exchange between the DCS and the UOS, enabling the simulation of external sensors and the creation of custom environments. The DCS offers a basic simulation for training and testing purposes, while the UOS provides a platform for designing complex scenarios with complex environments and sensor simulations. This simulation environment is beneficial for pilots, developers, and testers, allowing them to safely and effectively test drone behavior, control programs, and software algorithms in a controlled virtual space that closely mirrors real-world conditions. The system provides for the testing of manual and autonomous flight, with the option to transition seamlessly to real-world drone operation after testing is completed.

Although examples are presented with reference to drones, the same principles may be used to perform simulations with any other type of moving artifacts, such as vehicles, motorcycles, boats, ships, robots, submarines, airplanes, helicopters, construction equipment, buses, etc.

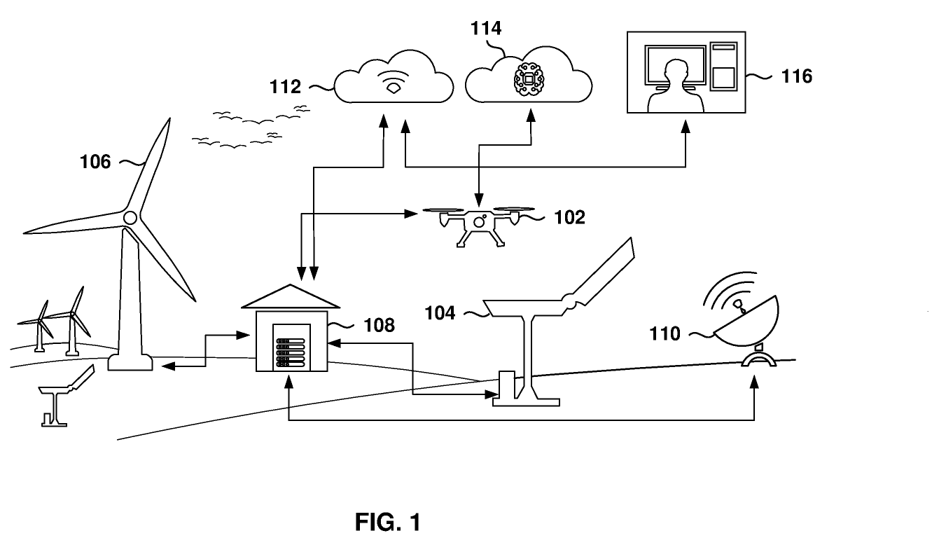

FIG. 1 illustrates a sample system for inspecting assets 106 using a drone 102. A user interfaces with a control program 116 to request an autonomous inspection of assets 106, e.g., a wind turbine. A data center 108 includes electronic equipment, including software and hardware for managing missions, storing data, analyzing the data, etc.

Additionally, cloud services 112 and 114 are used for data storage and for using computer processors to analyze the data. Once the user enters the request for inspection (e.g., communicated to the field via wireless communications 110), the drone 102 flies to the asset and captures sensor data (e.g., images of the turbines to detect defects, images of the ground to detect dead birds, measurements of gas sensor, temperature measurements, lidar measurements). A housing 104 hosts the drone 102 while not in use.

After the drone 102 returns to the housing 104, the data is uploaded, such as to one of the cloud services 112, 114. Data analysis is then performed on the collected data to determine problems. For example, image processing and defect detection are performed to analyze the data to detect defects in the wind turbines. The results may then be observed by the user via the user interface (UI) of the control program 116.

Each mission requires an authorization before it can be executed. In some example embodiments, the operation of the drone 102 is autonomous because the mission assigned to the drone 102 includes the required parameters for the drone 102 to fly to the required asset 106, capture the necessary data (e.g., multiple pictures of sections of each of the blades), package the data, and then download the data for analysis.

It is noted that some embodiments are presented with autonomous UAVs, but the same principles may be used for other autonomous apparatuses. Further, the inspections may involve many types of assets besides wind turbines, such as avian mortality assessment or agricultural crops.

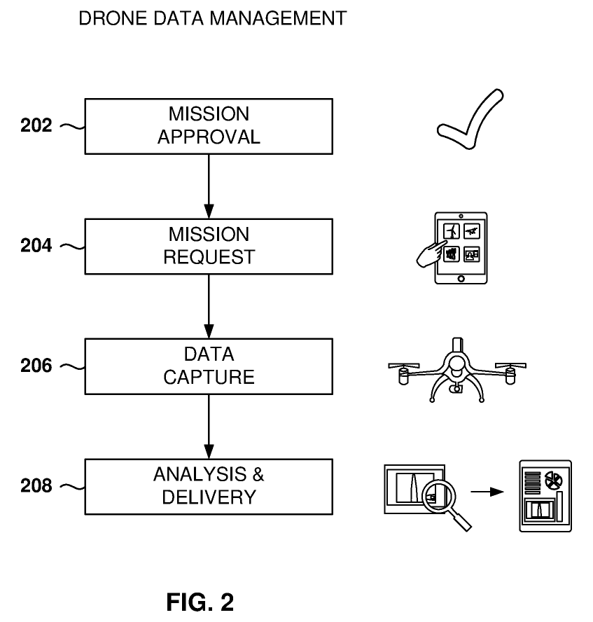

FIG. 2 is a flowchart of a method for drone data management, according to some example embodiments. The architecture for drone data management builds on use cases and enables the use of automated workflows.

At operation 202, the mission is approved. An administrator utilizes the management program to select a workflow and then enters the request. The authorization process includes approving the mission by one or more persons who have the authority to enable the mission.

After the mission is approved, the method flows to operation 204 where a mission request is generated. The mission is requested by an operator on the field who is authorized to initiate the mission.

The mission is then executed by the drone that travels to the programmed location to inspect the asset and capture the data 206. After the drone ends the task, the data captured by the drone is downloaded and placed in a package that is stored on a server, such as a cloud server.

The stored data is then analyzed, and the results are delivered to the user at operation 208. For example, the data may show images of a solar panel or a wind turbine, and the result may be a fault in one of the panels or turbines, such as a broken panel or a crack on a turbine blade. Additionally, the data collected may be used to capture condition information about the asset.

FIGS. 1 and 2 show scenarios for the use of drones. These scenarios are often complex, so testing a mission on the field may be costly and time-consuming because it requires setting up the drone and having the drone operator available. Thus, being able to simulate the operation of drones, particularly when executing complex missions, would be an excellent benefit for the development and testing of complex drone operations.

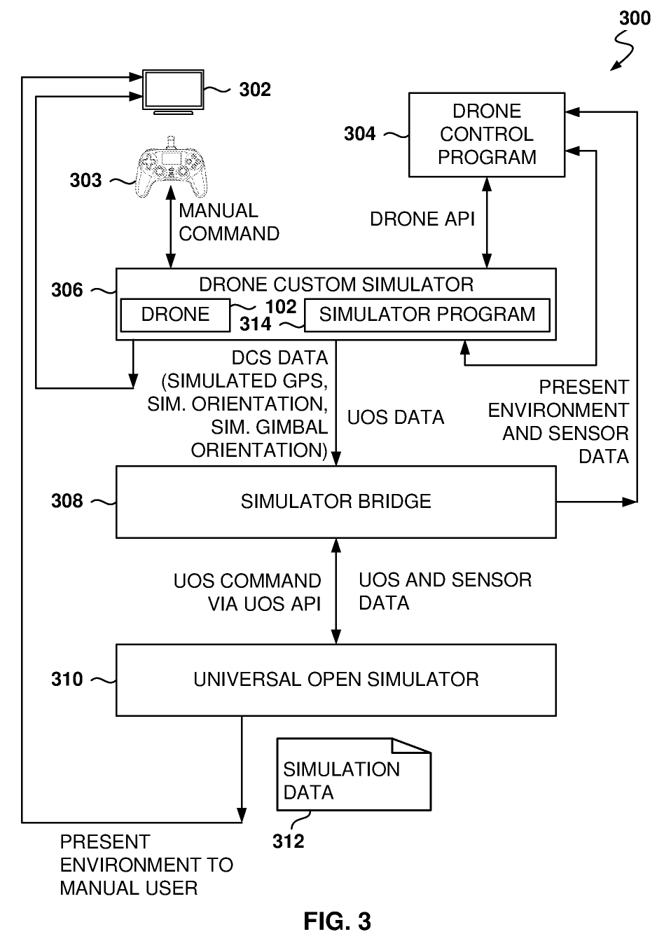

FIG. 3 illustrates a sample drone simulation environment 300. A drone simulator is a software application or system designed to replicate the behavior and characteristics of real-world drones in a virtual environment. These simulators are used for various purposes, including training pilots, testing new drone designs, practicing flight maneuvers, and developing autonomous flight algorithms.

Some drone simulators provide a realistic simulation of flight physics, allowing users to experience factors such as wind resistance, gravity, and aerodynamics. They may offer a variety of virtual environments, ranging from open landscapes to urban settings, to simulate different flying conditions.

Typically, users can control the simulated drone using various input devices, such as a joystick, gamepad, or keyboard, and view the drone’s perspective through a simulated first-person view (FPV) camera or third-person view. Some simulators also provide programmatic access (e.g., via an Application Programming Interface (API)) to perform drone operations.

For many drones in the market, the conventional approach for conducting flight simulations with the drone is dependent on the utilization of the drone-exclusive simulator provided by the drone manufacturer, which is referred to herein as the Drone Custom Simulator (DCS 306). In some examples, the DCS 306 includes the drone 102 and a simulator program 314. When a simulation is performed by the DCS 306, the drone 102 is configured to operate in simulation mode, which means that the drone will not move (e.g., arm propellers or motors).

The simulator program 314 executes on a separate computing device and emulates the physics for the simulation as if the drone were actually flying. The simulator program 314 interfaces with the drone and instructs the drone 102 to be in simulation mode so propellers are not activated.

The drone 102 and the simulator program 314 work together to "fly" the drone in the simulation. This way, the drone 102 gets the same commands as if it were actually flying, but instead of the drone physically flying (in real-world flight), the drone performs the simulation flight based on the inputs provided by the simulator program 314.

After a successful simulation, the DCP 304 can perform a real flight with the drone 102 using the same commands that were used during the simulation, and the real-life environment would appear the same as the environment used in the simulation. The DCP 304 gets the information directly from the drone 102 and the information that was provided by the simulator bridge 308 now comes from the real world.

In some examples, the DCS replicates the drone’s physical characteristics and the behavior of the control software within a vacant environment when operating in Hardware In the Loop (HIL) mode. The DCS permits developers and pilots to conduct tests on the native autopilot through the remote controller for manual flight or by employing software for autonomous flight within an open field while also receiving simulated information from the Global Positioning System and compass.

However, the DCS is often confined to scenarios that simulate an open field and lacks the capacity to integrate external elements or obstacles, or to incorporate additional sensors such as lidar sensors.

Furthermore, in some cases, the DCS enables the simulation of controlling gimbal payloads; however, the DCS does not provide camera imagery from the simulation environment. Additionally, due to the DCS's inability to permit the introduction of objects into the environment, navigational testing capabilities are constrained. There is also an absence of a recognized method for integrating the DCS with alternative simulators that offer more comprehensive simulation functionalities. One example of a DCS is the DJI M300 simulator from DJI Enterprise for their Matrice 300 RTK drone.

In contrast, other simulators, referred to herein as Universal Open Simulator (UOS), such as Microsoft AirSim®, provide very versatile simulation options that allow features such as the integration of sensors and the definition of complex flying environments that include buildings, roads, bridges, weather conditions, etc.

Microsoft AirSim, an open-source simulator, leverages the Unreal Engine for the generation of high-fidelity simulations pertinent to Unmanned Aerial Systems (UAS). This simulator enables the creation of bespoke environments, the incorporation of diverse sensors, and the rendering of photorealistic imagery. AirSim includes an integrated autopilot and offers the capability for direct interfacing with MAVLink-compatible autopilots, including PX4 and ArduPilot. This feature allows for the execution of realistic physics simulations in tandem with autopilot functionalities. However, Microsoft AirSim does not provide integration with certain drone makes and brands, thus limiting the simulation of drone behavior within the confines of the drone’s simulator provided by the drone manufacturer.

In response to the aforementioned challenges associated with working with specific drones, techniques are presented for integrating a DCS, which facilitates native autopilot logic and physics, with a UOS such as Microsoft AirSim. This integration offers the capability to simulate external sensors and create custom environments. The solution employs a software-based bridge to facilitate information exchange between the two platforms.

The Examples presented relate to integration with AirSim, but the same principles may be used to integrate the use of other UOSs. Therefore, the examples should not be interpreted as exclusive or limiting but rather illustrative.

AirSim is an open-source, cross-platform simulator for drones, cars, and other moving devices that supports software-in-the-loop simulation with popular flight controllers such as PX4 and ArduPilot and hardware-in-loop with PX4 for physically and visually realistic simulations. AirSim exposes APIs for programmatic interaction with the vehicle in the simulation. The API may also be used to retrieve images, get state information, control the vehicle, and so on.

In some examples, AirSim is executed in an environment with physics disabled because the DCS 306 provides the location and motion simulation. Thus, the GPS position and orientation of the virtual drone are provided as input to AirSim.

Referring to FIG. 3, the sample drone simulation environment 300 includes modules for the interaction between a manual user (e.g., a drone operator flying the drone using a controller) and a drone control program 304 with a simulated drone flight environment.

The manual user enters simulation commands using a controller 303 connected to the drone 102 of the DCS 306. These commands are interpreted by a Drone Custom Simulator (DCS), which is designed to emulate the behavior of a physical drone’s flight control system. In some examples, the DCS offers a Software Development Kit (SDK) for interfacing with the drone and a basic simulator for training purposes.

In some examples, the DCS 306 provides a basic environment where users can simulate drone flight without actually activating the propellers or causing any harm. Still, the DCS 306 does not provide options for more complex operations, such as adding sensors, cameras, lidar, etc.

The drone control program 304 interfaces with the DCS 306 via computer commands transmitted over a computer communication medium, e.g., a network. In some examples, the commands are transmitted via a drone API, which is the API associated with the SDK provided by the DCS manufacturer for programmatic access to the drone.

In some examples, the DCS 306 processes the manual commands and the drone API commands to update the simulation executing on the DCS. The DCS is responsible for simulating the drone’s behavior based on the received commands. The result of these commands is the update of the simulation, which results in the generation of DCS data related to the simulation, such as updated simulated GPS position of the drone, simulated orientation of the drone, simulated gimbal orientation of the drone, etc.

In some examples, the drone 102 offers different types of payloads that mount onto the drone 102, e.g., a lidar-camera combination, and a gimbal-mounted camera. In some examples, the DCS 306 may not support simulating the gimbal behavior, but since the commands sent to the drone for gimbal control do make it to the gimbal, the simulator bridge 308 interfaces with the gimbal to make the operation work seamlessly and the result is a functional camera with gimbal).

The DCS data is accessible to the drone control program 304 to get updates on the virtual drone. It is noted that this simulated data mirrors the data that would be provided by the actual drone flying, which means that once the testing is done with the virtual drone, the same commands may be used to access the real drone. This way, the testing environment for the drone control program 304 will mirror the real-world environment.

In some examples, the DCS provides simulated GPS information and a map for software interfacing with the drone, allowing access to flying data even when the drone is grounded. The GPS information and the map are shown to the user on the controller screen, just like they would see when flying the drone. This feature is particularly beneficial for pilots and developers, especially in regions with limited sunlight, like North Dakota. In such areas, where flying may not be possible due to weather conditions, the ability to access GPS information while on the ground is valuable for maintaining production and development activities. This capability is also helpful for test pilots who may need to fly a drone manually for testing purposes.

The simulator bridge 308 serves as an intermediary that facilitates communication between the DCS 306 and the universal open simulator (UOS 310). The simulator bridge 308 interacts with the 306 via the drone API to get the simulated drone information.

The simulator bridge 308 translates the DCS data into UOS commands that are sent to the UOS 310 via the UOS API, which is the API provided by the UOS manufacturer to access the features of the UOS 310 programmatically. In some examples, the UOS command is a command to place the virtual UOS drone in a place in space according to the simulated GPS coordinates with the simulated drone orientation and simulated drone gimbal orientation.

Further, the UOS data may be read by the simulator bridge 308 and made available to the DCS 306. This way, the drone control program 304 may access UOS data as if it were real-world data obtained via the drone API.

In another configuration, the drone control program 304 could utilize the UOS 310 directly, without using the DCS 306, and letting the UOS 310 run the physics simulation. However, this approach would not allow for the testing of the drone API provided by the drone manufacturer, potentially overlooking issues that may arise if the software malfunctions or fails to communicate effectively with the drone API. Further, the accuracy of the UOS 310 for simulating the drone flying will not be as accurate as the DCS 306 provided by the manufacturer that has more experience with the particular drone model.

The drone API is used to access the GPS information. The DCS 306 may be used to monitor takeoff and elevation over ground level based on the altitude provided by GPS. The simulator bridge 308 processes the GPS location, home location, and orientation of the drone, converting the location into (x, y, z) three-dimensional coordinates with the origin (0, 0, 0) at the home location of the drone, which is the location where the drone took off. However, other origin points may be used. The coordinates are then sent to the UOS 310, and then the drone is positioned in the UOS 310 based on these coordinates. The UOS 310 operates without simulating physics because the DCS provides the location. As the drone moves in the DCS 306, the position of the drone in the UOS 310 is updated accordingly.

The UOS 310 operates without physics calculations because the position is determined by the DCS 306. The drone is then situated within the UOS 310 simulation environment. The UOS 310 allows users to design their own environments, including structures and diverse landscapes such as remote areas or snowy terrain. This flexibility enables the simulation of a wide range of scenarios. Consequently, the drone benefits from the physics simulation by the DCS 306 and the sensor simulations, such as camera and lidar, provided by the UOS 310. For example, lidar data generated in the UOS 310 can be utilized by the drone control program 304, along with camera imagery and other sensor data.

The UOS 310 is a versatile platform that can simulate various environments and scenarios, providing a realistic backdrop for the drone simulation. The UOS 310 processes the commands or updates received from the simulator bridge 308 to update the simulation executed by the UOS 310 and generates simulation data 312. Thus, two simulations are executed simultaneously: the DCS simulation and the UOS simulation, with the simulator bridge 308 acting as the glue that makes them work together and stay synchronized.

The drone control program 304 may get information from the simulator bridge 308, such as lidar data based on the environment and the drone’s location, camera imagery (e.g., RGB, IR) based on the environment and the location of the virtual camera in the virtual drone, sensor data provided by the sensors in the drone, etc. The simulator bridge 308 would mimic whatever endpoint the DCP would be expecting in real life.

The progress of the DCS simulation and the UOS simulation may be presented to the manual user on a display 302 or the map presented on the controller 303. Further, environment and sensor data information from both simulations are presented to the drone control program 304. A user may follow the progress of the drone control program 304 via a user interface presented on the display 302 of a computing device.

The simulation data 312 enables the testing of software algorithms, analysis of flight data, or training machine learning models in a controlled and safe virtual space.

The sensor data from the UOS may be presented to the user on the display 302. In some examples, the UOS 310 is able to plot lidar points (that could not be seen in real life) on the display 302. Further, the display 302 may be used to present algorithmic debug information, such as “Here is where the algorithm calculates that the hub center is.” This option is particularly helpful when developing algorithms since there is no way to see these debug information and results in real life.

It is noted that once testing is completed, the drone control program may execute real-world applications by simply using the drone API to interact with a real drone instead of a virtual drone. The simulator bridge 308 and UOS 310 will not be required after the testing as the drone control program 304 will communicate directly with the drone and get information from the drone on real data, such as the current GPS and orientation of the drone. Similarly, a manual user will send commands to the real drone and observe the progress using the information provided by the drone.

As an example, the drone control program 304 is for inspecting a wind turbine and has to perform two operations:

1. Climb to a known approximate height of a turbine hub and

2. Use lidar data to run an algorithm that detects the exact position of the turbine hub.

Regarding operation 1, the scope is given by asset configuration parameters, which is part of the information on the mission request. For example, this value is given with an accuracy of about a meter, which is why the second operation is needed to determine the exact location.

In some examples, the DCS 306 includes a Payload SDK set and an Onboard SDK. For the turbine-inspection example, any SDK may be used.

In real life, for operation 1, the drone control program 304 sends a signal to the drone using the command positionAndYawCtrl (via the Onboard SDK) or the DjiFlightController_ExecuteJoystickAction (via the Payload SDK). When the real-world drone receives the command, the drone will climb up to the altitude requested.

The command positionAndYawCtrl is used to send the drone a movement command in the NEU (north, east, up) space to move by a given offset. It is used to control the position and yaw angle of the vehicle. The format is void Control::positionAndYawCtrl (float32_t x, float32_t y, float32_t z, float32_t yaw), where x is the position set-point in x axis of ground frame (m), y is the position set-point in y axis of ground frame (m), z is the position set-point in z axis of ground frame (m), and yaw is the yaw set-point (deg). The command DjiFlightController_ExecuteJoystickAction provides the same functionality as positionAndYawCtrl.

During the flight, the drone control program 304 has access to lidar information from the real-world lidar showing the turbine hub, and the drone control program 304 then runs an algorithm to detect the exact position of the turbine hub.

During the simulation, the drone control program 304 sends the same commands positionAndYawCtrl (via the Onboard SDK) or DjiFlightController_ExecuteJoystickAction (via the Payload SDK) to the DCS 306. That is, the same command sent by the drone control program 304 to the drone 102 that would be sent in real life.

In response to the command received, the simulated drone in the DCS 306 simulator climbs up to the requested altitude. As the virtual drone moves, the drone’s GPS location changes, and the simulator bridge 308 monitors the GPS location of the virtual drone given by the DCS 306 using the command getValue<Telemetry::TOPIC_GPS_FUSED> (via the Onboard SDK) or the command getLatestValueOfTopic <Topic:: DJI_FC_SUBSCRIPTION _TOPIC_POSITION_FUSED> (via the Payload SDK).

The parameter TOPIC_GPS_FUSED is to get the drone’s latitude, longitude, and altitude, and it provides the drone’s GPS/IMU fused X-Y position and barometric altitude (put together in a single topic for convenience). The parameter DJI_FC_SUBSCRIPTION _TOPIC_POSITION_FUSED provides the same functionality as TOPIC_GPS_FUSED.

The simulator bridge 308 converts the current GPS location of the virtual drone into (x, y, z) offsets from the home GPS position (the position where the drone started the flight) and sends a command to the UOS 310 to place the virtual drone into the given (x, y, z) location using the API command simSetVehiclePose of Microsoft AirSim. As a result, the virtual drone also moves in the UOS 310 space to reach the simulated turbine hub. In some examples, the drone orientation is also sent to the UOS 310 since a 3D pose is made of both location and orientation.

During operation 2 of the simulation, the simulator bridge 308 provides access to the DCS 306 of the lidar data from the UOS as if the lidar data is coming from a real lidar sensor.

In some examples, a Robot Operating System (ROS) interface is used for communications. ROS is not exactly an operating system in the traditional sense but rather a set of software frameworks for building robot applications. ROS provides libraries, tools, and conventions to simplify the task of creating complex and robust robot behavior across a wide variety of robotic platforms.

In some examples, the drone 102 provides a ROS interface, and the DCP 304 may use ROS to communicate with the drone 102. In some examples, the drone does not provide a ROS interface, so the DCP 304 has to use the drone API for communications. In some examples, the simulator bridge 308 is ROS enabled, and the ROS interface may be used for communications between the DCP 304 and the simulator bridge 308.

The simulator bridge 308 exposes the UOS 310 lidar information as a ROS topic that the DCP 304 can access. This is similar to the real-world scenario where the physical lidar is connected through a software driver that exposes the real-world lidar data as a ROS topic. This way, the DCP 304, in both cases (real life and simulation), would listen to a lidar ROS topic to get lidar information where the source of this lidar information is either the UOS 310 or an actual lidar sensor.

During operation 2 of the simulation, the drone control program 304 gets the lidar information provided by the bridge ROS node, which gets it from the UOS 310 to run the algorithm that detects the exact position of the turbine hub. In real life, the drone control program 304 gets the information from the ROS node that gets the actual information from the lidar device.

This example shows that for the drone control program 304, the real-world situation and the simulated situation appear identical in terms of what the drone control program 304 “sees” (drone and sensor information) and what the drone control program 304 is able to control.

This example scenario may be expanded to cover more complex operations, such as “use the lidar information as the drone flies to determine which direction to travel as you track the turbine blade.”

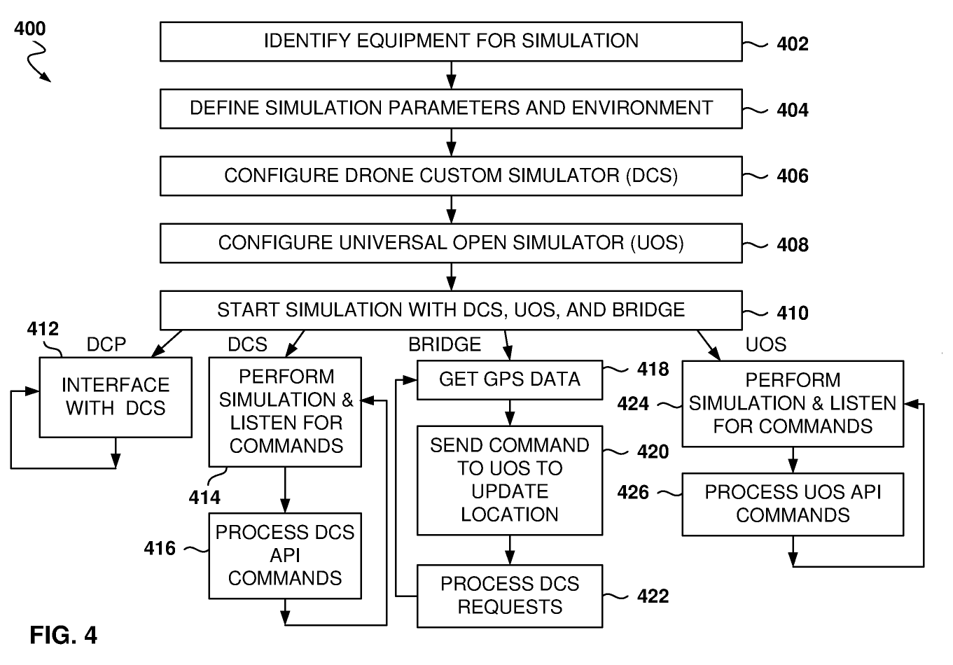

FIG. 4 is a flowchart of a method 400 for navigating a drone in a customized simulation environment, according to some examples. While the various operations in this flowchart are presented and described sequentially, one of ordinary skill will appreciate that some or all of the operations may be executed in a different order, be combined or omitted, or be executed in parallel.

Operation 402 is to identify the equipment for simulation, e.g., the drone type, the DCS, and the UOS. From operation 402, the method 400 flows to operation 404 to define the simulation parameters and the environment, which involves specifying the variables and conditions under which the simulation will run.

Next, operation 406 is to configure the DCS for the simulation. From operation 406, the method 400 flows to operation 408 to configure the UOS, which involves preparing the more general simulator that can work with various types of drones, sensors, and environment simulation needs.

The simulation begins at operation 410 by starting the simulation in the DCS, the UOS, and the bridge.

During the simulation, the modules that participate in the simulation operate in parallel, that is, the drone control program (DCP), the DCS, the bridge, and the UOS. The illustrated example is for the use of the DCP, but the same mode of operation may be used when the virtual drone is operated manually.

At operation 412, the DCP interfaces with the DCS to send commands and receive responses with the corresponding data. The data received from the DCS may include data originated by the UOS and accessed via the DCS.

The DCP can be tested through simulation runs. Any bugs encountered during the simulation may be addressed, and after successful testing, the DCP is ready for operational use with the real drone.

The DCS performs operations 414 and 416, which are performed in a loop. At operation 414, the DCS performs the simulation of the drone operation while listening to commands received via the drone API. At operation 416, the DCS processes the commands received via the drone API.

During the DCS simulation, the drone’s GPS location will ascend within the simulator environment, providing simulated data such as GPS location, orientation heading, IMU information, and gimbal status. This data is also made available via the API for external monitoring and analysis. In response to API queries regarding the drone’s GPS location and altitude, the drone in simulation mode will report increasing simulated altitudes, reflecting its virtual flight status.

The bridge performs operations 418, 420, and 422 performed in a loop. At operation 418, the bridge periodically gets the GPS data from the DCS and then sends, at operation 420, a UOS API command to the UOS to update the location of the drone in the UOS simulation. Further, if there are any requests from the DCP to get UOS data or perform some other operation, the bridge processes the DCP request and sends the corresponding UOS command to the UOS.

The UOS performs operations 424 and 426 in a loop. At operation 424, the UOS performs the UOS simulation and listens for commands. If a command is received, the UOS processes the received command (e.g., update the GPS location of the drone, get data from the lidar sensor in simulation).

The method 400 ensures a continuous and interactive simulation environment in which the DCS, the bridge, and the UOS are actively involved in the simulation process.

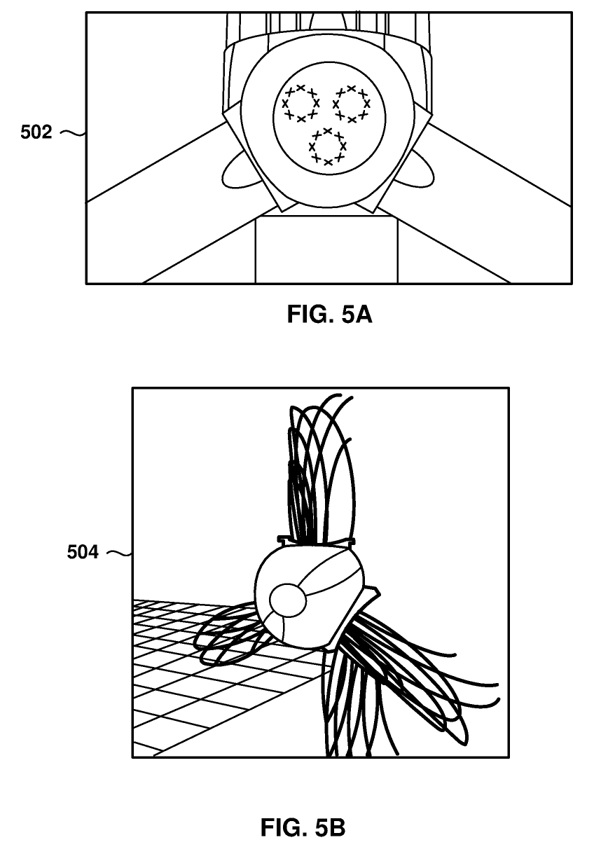

FIGS. 5A-5B show virtual images obtained during a simulation flight, according to some examples. In the illustrated example, the programmatic control being tested involves the inspection of a wind turbine. A program is utilized to test the turbine.

A drone service provider may require their pilots to practice flying a drone for a customer, e.g., flying under and around a bridge. The pilots are advised to practice using the DCS, which mimics the actual remote control used with the drone. This practice allows the pilots to familiarize themselves with the controls and operations of the drone. By practicing in the simulator, pilots can avoid accidents such as colliding with a bridge during real flights, which is a concern for regulatory bodies like the FAA.

Image 502 is a virtual image of a turbine hub. The UOS generates the image by using a virtual camera that takes a picture within the UOS environment based on the location and orientation of the virtual camera. If the DCP changed the access to interface with the real drone, then the drone would obtain a similar real image of the real turbine hub.

Image 504 corresponds to a virtual lidar projection generated with the virtual sensor in the UOS environment. If the DCP changed the access to interface with the real drone, then the lidar in the drone would obtain a similar real image of the turbine.

In some cases, the DCS would not show such details, displaying only a green field, because the DCS does not support complex environments like the ones supported by the UOS. Lidar simulation is important for tasks like programming a drone to ascend and halt upon detecting a wind turbine. Therefore, if the DCS lacks the capability to simulate wind turbines, lidar, or camera feeds, the incorporation of the UOS in the solution allows for the simulation of lidar readings.

If lidar data were used to adjust the drone's flying and testing were performed with the DCS alone, where the DCS lacks lidar simulation, it would not be possible to test this scenario. For example, the drone would continue to ascend without interruption due to the absence of lidar feedback.

By integrating the wind turbine into the simulation environment, the drone receives point cloud data, enabling a comprehensive analysis. This data, along with GPS coordinates, can be utilized by the DCP to make informed decisions, such as halting movement. Commands issued to stop movement prompt the drone in the simulation to cease its motion in near real-time, with continuous updates. The drone will adjust altitude accordingly, reaching the desired hub height.

In a more straightforward scenario, manually controlling the drone involves adjusting the throttle on the controller to ascend. The drone, operating in DJI simulation mode, responds to commands from the controller by ascending. Real-time GPS updates are relayed to the UOS, visually representing the drone’s ascent trajectory. Users can observe the drone’s movements from an aerial perspective, facilitating practice maneuvers and enhancing situational awareness.

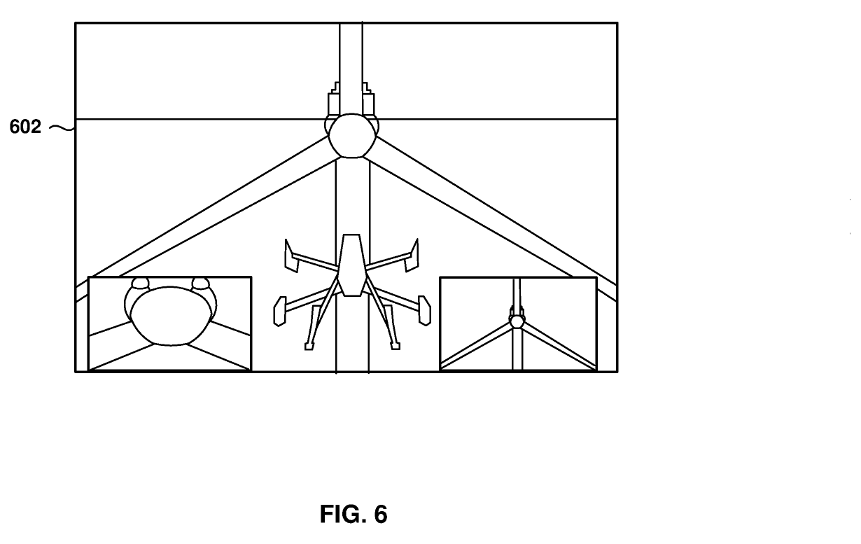

FIG. 6 is an image 602 provided by one simulator during flight, according to some examples. Image 602 illustrates a user interface for a flight simulation system. The interface displays a forward view from the cockpit of an aircraft (e.g., the drone), with the horizon visible in the distance. The central portion of the view shows the wind turbine, with inside windows including a close-up look at the turbine hub and a more comprehensive view of the turbine. The graphical representation of the aircraft’s structure provides a reference point for the user to maintain orientation and control during the simulation.

The user interface further includes overlaid elements that provide flight information, such as a text-based heads-up display (HUD) that presents data such as altitude, speed, and other flight parameters. This HUD is designed to provide real-time feedback to the user without obstructing the primary field of view.

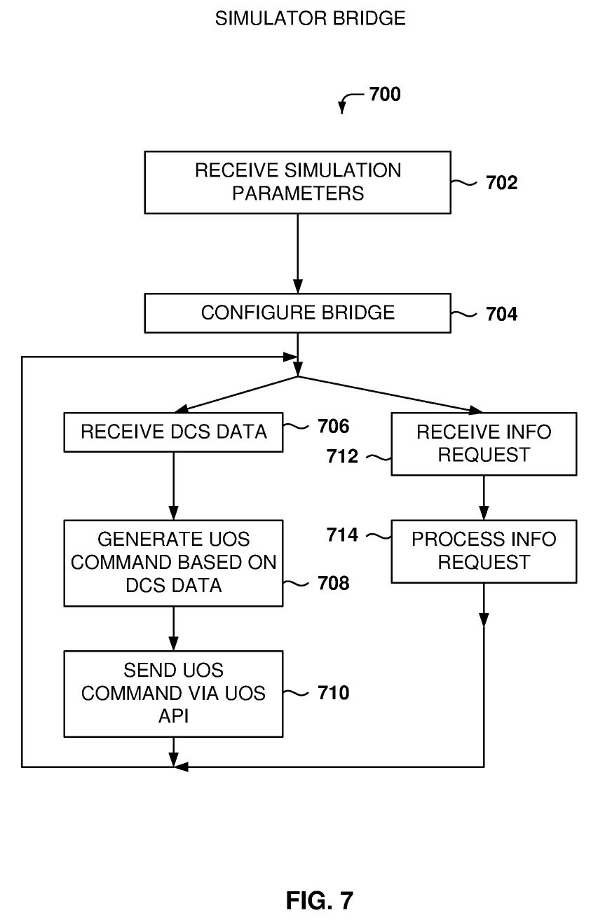

FIG. 7 is a flowchart of a method 700 for the simulator bridge operations, according to some examples. While the various operations in this flowchart are presented and described sequentially, one of ordinary skill will appreciate that some or all of the operations may be executed in a different order, be combined or omitted, or be executed in parallel.

Operation 702 involves receiving simulation parameters, such as drone model, environment, sensors configured, parameters to configure the bridge, etc.

Operation 704 is executed to configure the bridge. This operation translates the received parameters (e.g., how to access the DCS and the UOS) into a specific setup for the simulator bridge, ensuring that the simulation environment reflects the desired conditions.

Once the simulation begins, the bridge will periodically update the position of the drone and process other DCS data in operations 706, 708, and 710, which are performed in a loop. Operation 706 entails receiving DCS data, such as the GPS data for the current location of the virtual drone.

From operation 706, the method 700 flows to operation 708 for generating UOS commands based on the DCS data received in the previous operation. For example, the UOS command may be the request to change the location of the drone in the virtual space.

From operation 708, the method 700 flows to operation 710 for sending the UOS command via the UOS API.

Further, if the bridge receives a request for information at operation 712, then the bridge will process the information request and return the requested data (e.g., perform a lidar scan now or capture an image with the camera) at operation 714.

The software bridge facilitates the transfer of information between the UOS API and the drone’s GPS location. When the simulation starts, the bridge records the initial GPS location (0, 0, 0) and then continuously updates the drone’s location by converting GPS coordinates to (x, y, z) coordinates for placement using the UOS API.

In a scenario where the drone is not in simulation mode and actual GPS locations are being used, the software bridge is removed, leaving a direct connection between the DCP and the drone via the drone API. This streamlined process closely mirrors real-world operations, making deployment straightforward by simply removing the simulation stack after completing the simulation testing.

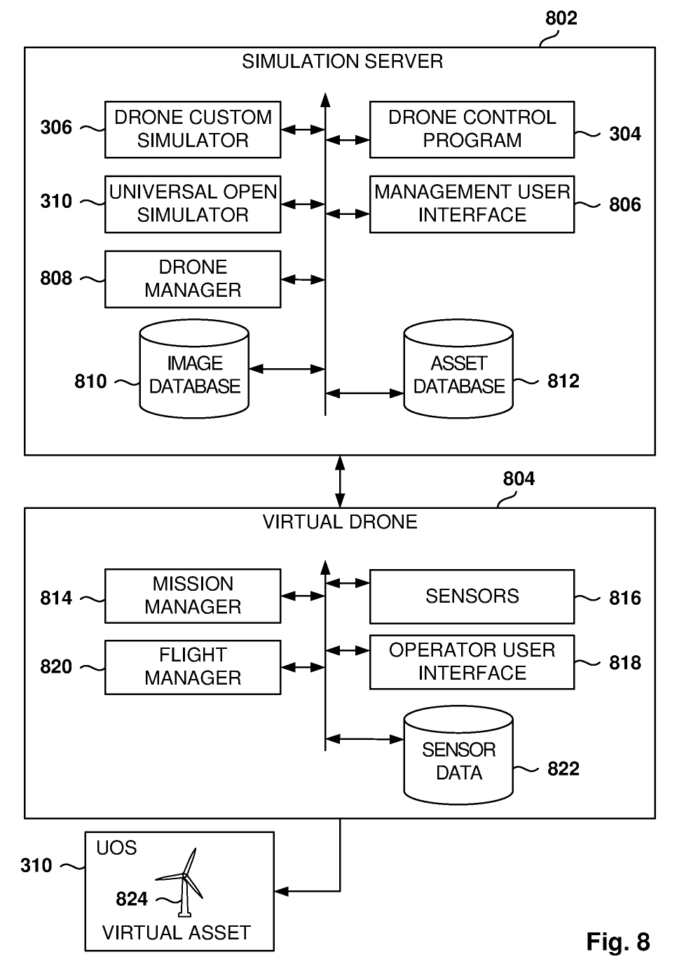

FIG. 8 illustrates a sample architecture for implementing example embodiments. The system is divided into two main components: the simulation server 802 and the virtual drone 804.

The simulation server 802 is responsible for the overall management and simulation of drone operations. Within the simulation server 802, there is a DCP 304 that interfaces with both the DCS 306 and the UOS 310. These simulators provide the necessary virtual environment and physics to accurately represent drone flight and behavior within a simulated context.

Additionally, the simulation server 802 includes a management user interface 806, which allows an operator to interact with the system, set parameters, and manage the simulation. The drone manager 808 oversees the operation of the simulated drones and coordinates between the different simulators and databases.

The simulation server 802 further includes two databases: the image database 810, which stores images from the drone operations, and the asset database 812, which contains information about virtual assets used within the simulation environment.

The virtual drone 804 represents the simulated drone within the system. The virtual drone 804 includes a mission manager 814 that plans and executes missions for the virtual drone and sensors 816 that provide simulated sensory data that a real drone’s sensors would typically gather during flight. This data obtained by the sensors is stored in the sensor data 822 database.

An operator user interface 818 allows the user to interact with the virtual drone 804, providing controls and feedback as if they were operating a real drone. The flight manager 820 is responsible for managing the virtual drone’s flight dynamics, ensuring that the drone’s movements within the simulation are realistic and adhere to the parameters set by the mission manager 814.

Further, the virtual asset 824 in the UOS 310 represents any virtual entities or objects that the simulated drone might interact with during its mission.

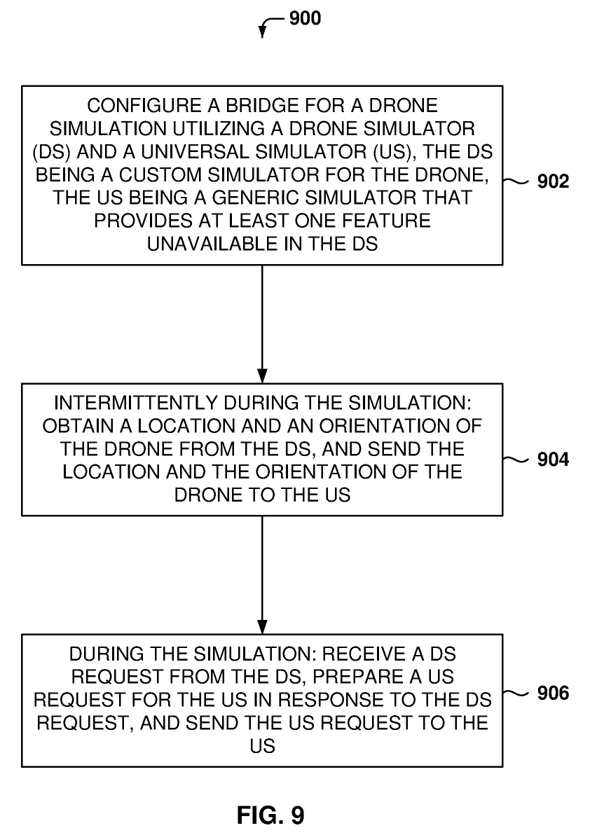

FIG. 9 is a flowchart of a computer-implemented method 900 for providing a customized simulation environment for navigating and testing a virtual drone, according to some examples. While the various operations in this flowchart are presented and described sequentially, one of ordinary skill will appreciate that some or all of the operations may be executed in a different order, be combined or omitted, or be executed in parallel.

Operation 902 is for configuring a bridge for a drone simulation utilizing a drone simulator (DS) and a universal simulator (US). The DS is a custom simulator for the drone, and the US is a generic simulator that provides at least one feature unavailable in the DS.

From operation 902, the method 900 flows to operation 904 for intermittently during the simulation, performing operations for obtaining a location and an orientation of the drone from the DS, and sending the location and the orientation of the drone to the US.

From operation 904, the method 900 flows to operation 906 for, during the simulation, perform operations for receiving a DS request from the DS, preparing a US request for the US in response to the DS request, and sending the US request to the US.

In some examples, the method 900 further comprises receiving a response to the US command, and sending information about the response to the DS.

In some examples, the US performs the simulation with physics disabled and the US updates the location of the drone based on the intermittently received location and orientation of the drone.

In some examples, the DS provides the same interface as an interface provided by a real drone, where a control program is tested by interfacing with the DS utilizing same commands to be used with the real drone when the real drone is controlled by the control program.

In some examples, the method 900 further comprises receiving, by the DS, a command from the control program; and updating the simulation in the DS based on the command from the control program, where the bridge updates the location and the orientation of the drone in the US based on changes to the location and the orientation of the drone in the DS.

In some examples, the location of the drone is received as a global positioning system (GPS) location from the DS, and sending the location and the orientation of the drone to the US further comprises translating the GPS location to coordinates for a three-dimensional space with origin in a home location of the drone, and sending the coordinates to the US.

In some examples, the drone is configured to provide a Robot Operating System (ROS) interface, where the US provides sensor information via the ROS that is accessible by the bridge and the DS.

In some examples, the simulation is for manual flying of the drone based on manual flight commands for the drone, where the DS processes the manual flight commands to update the location and the orientation of the drone.

In some examples, the US is configurable to include buildings and bridges in the simulation, where the DS is not configurable to include buildings and bridges in the simulation.

In some examples, sending the location and the orientation of the drone to the US comprises sending the location of the drone, the orientation of the drone, and a gimbal orientation of the drone to the US.

Another general aspect is for a system that includes a memory comprising instructions and one or more computer processors. The instructions, when executed by the one or more computer processors, cause the one or more computer processors to perform operations comprising: configuring a bridge for a drone simulation utilizing a drone simulator (DS) and a universal simulator (US), the DS being a custom simulator for the drone, the US being a generic simulator that provides at least one feature unavailable in the DS; intermittently during the simulation: obtaining a location and an orientation of the drone from the DS; and sending the location and the orientation of the drone to the US; and during the simulation: receiving a DS request from the DS; preparing a US request for the US in response to the DS request; and sending the US request to the US.

In yet another general aspect, a tangible machine-readable storage medium (e.g., a non-transitory storage medium) includes instructions that, when executed by a machine, cause the machine to perform operations comprising: configuring a bridge for a drone simulation utilizing a drone simulator (DS) and a universal simulator (US), the DS being a custom simulator for the drone, the US being a generic simulator that provides at least one feature unavailable in the DS; intermittently during the simulation: obtaining a location and an orientation of the drone from the DS; and sending the location and the orientation of the drone to the US; and during the simulation: receiving a DS request from the DS; preparing a US request for the US in response to the DS request; and sending the US request to the US.

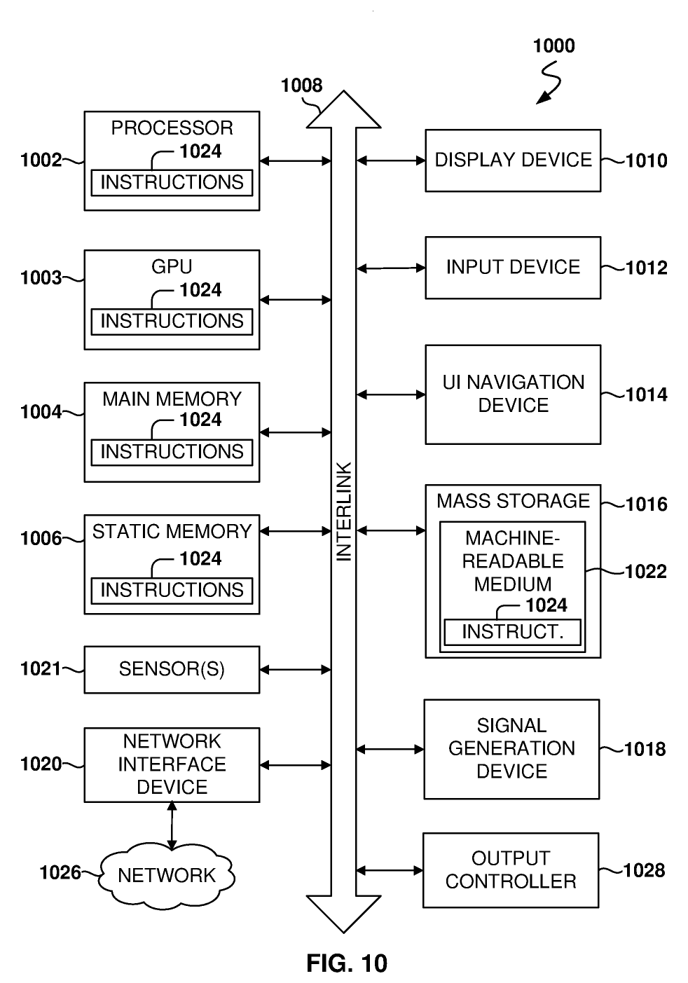

FIG. 10 is a block diagram illustrating an example of a machine 1000 upon or by which one or more example process examples described herein may be implemented or controlled. In alternative examples, the machine 1000 may operate as a standalone device or be connected (e.g., networked) to other machines. In a networked deployment, the machine 1000 may operate in the capacity of a server machine, a client machine, or both in server-client network environments. In an example, the machine 1000 may act as a peer machine in a peer-to-peer (P2P) (or other distributed) network environment. Further, while only a single machine 1000 is illustrated, the term “machine” shall also be taken to include any collection of machines that individually or jointly execute a set (or multiple sets) of instructions to perform any one or more of the methodologies discussed herein, such as via cloud computing, software as a service (SaaS), or other computer cluster configurations.

Examples, as described herein, may include, or may operate by, logic, various components, or mechanisms. Circuitry is a collection of circuits implemented in tangible entities, including hardware (e.g., simple circuits, gates, logic). Circuitry membership may be flexible over time and underlying hardware variability. Circuitries include members that may, alone or in combination, perform specified operations when operating. In an example, the hardware of the circuitry may be immutably designed to carry out a specific operation (e.g., hardwired). In an example, the hardware of the circuitry may include variably connected physical components (e.g., execution units, transistors, simple circuits), including a computer-readable medium physically modified (e.g., magnetically, electrically, by moveable placement of invariant massed particles) to encode instructions of the specific operation. In connecting the physical components, the underlying electrical properties of a hardware constituent are changed (for example, from an insulator to a conductor or vice versa). The instructions enable embedded hardware (e.g., the execution units or a loading mechanism) to create members of the circuitry in hardware via the variable connections to carry out portions of the specific operation when in operation. Accordingly, the computer-readable medium is communicatively coupled to the other circuitry components when the device operates. In an example, any of the physical components may be used in more than one member of more than one circuitry. For example, under operation, execution units may be used in a first circuit of a first circuitry at one point in time and reused by a second circuit in the first circuitry or by a third circuit in a second circuitry at a different time.

The machine 1000 (e.g., computer system) may include a hardware processor 1002 (e.g., a central processing unit (CPU), a hardware processor core, or any combination thereof), a graphics processing unit (GPU 1003), a main memory 1004, and a static memory 1006, some or all of which may communicate with each other via an interlink 1008 (e.g., bus). The machine 1000 may further include a display device 1010, an alphanumeric input device 1012 (e.g., a keyboard), and a user interface (UI) navigation device 1014 (e.g., a mouse). In an example, the display device 1010, alphanumeric input device 1012, and UI navigation device 1014 may be a touch screen display. The machine 1000 may additionally include a mass storage device 1016 (e.g., drive unit), a signal generation device 1018 (e.g., a speaker), a network interface device 1020, and one or more sensors 1021, such as a Global Positioning System (GPS) sensor, compass, accelerometer, or another sensor. The machine 1000 may include an output controller 1028, such as a serial (e.g., universal serial bus (USB)), parallel, or other wired or wireless (e.g., infrared (IR), near field communication (NFC)) connection to communicate with or control one or more peripheral devices (e.g., a printer, card reader).

The processor 1002 refers to any one or more circuits or virtual circuits (e.g., a physical circuit emulated by logic executing on an actual processor) that manipulates data values according to control signals (e.g., commands, opcodes, machine code, control words, macroinstructions, etc.) and which produces corresponding output signals that are applied to operate a machine. A processor 1002 may, for example, include at least one of a Central Processing Unit (CPU), a Reduced Instruction Set Computing (RISC) Processor, a Complex Instruction Set Computing (CISC) Processor, a Graphics Processing Unit (GPU), a Digital Signal Processor (DSP), a Tensor Processing Unit (TPU), a Neural Processing Unit (NPU), a Vision Processing Unit (VPU), a Machine Learning Accelerator, an Artificial Intelligence Accelerator, an Application Specific Integrated Circuit (ASIC), a Field Programmable Gate Array (FPGA), a Radio-Frequency Integrated Circuit (RFIC), a Neuromorphic Processor, a Quantum Processor, or any combination thereof.

The processor 1002 may further be a multi-core processor having two or more independent processors (sometimes referred to as “cores”) that may execute instructions contemporaneously. Multi-core processors contain multiple computational cores on a single integrated circuit die, each of which can independently execute program instructions in parallel. Parallel processing on multi-core processors may be implemented via architectures like superscalar, VLIW, vector processing, or SIMD that allow each core to run separate instruction streams concurrently. The processor 1002 may be emulated in software, running on a physical processor, as a virtual processor or virtual circuit. The virtual processor may behave like an independent processor but is implemented in software rather than hardware.

The mass storage device 1016 may include a machine-readable medium 1022 on which one or more sets of data structures or instructions 1024 (e.g., software) embodying or utilized by any of the techniques or functions described herein. The instructions 1024 may also reside, completely or at least partially, within the main memory 1004, within the static memory 1006, within the hardware processor 1002, or the GPU 1003 during execution thereof by the machine 1000. For example, one or any combination of the hardware processor 1002, the GPU 1003, the main memory 1004, the static memory 1006, or the mass storage device 1016 may constitute machine-readable media.

While the machine-readable medium 1022 is illustrated as a single medium, the term “machine-readable medium” may include a single medium or multiple media (e.g., a centralized or distributed database and associated caches and servers) configured to store one or more instructions 1024.

The term “machine-readable medium” may include any medium that is capable of storing, encoding, or carrying instructions 1024 for execution by the machine 1000 and that causes the machine 1000 to perform any one or more of the techniques of the present disclosure or that is capable of storing, encoding, or carrying data structures used by or associated with such instructions 1024. Non-limiting machine-readable medium examples may include solid-state memories and optical and magnetic media. For example, a massed machine-readable medium comprises a machine-readable medium 1022 with a plurality of particles having invariant (e.g., rest) mass. Accordingly, massed machine-readable media are not transitory propagating signals. Specific examples of massed machine-readable media may include non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; and CD-ROM and DVD-ROM disks.

The instructions 1024 may be transmitted or received over a communications network 1026 using a transmission medium via the network interface device 1020.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented separately. These and other variations, modifications, additions, and improvements fall within the scope of the subject matter herein.

The examples illustrated herein are described in sufficient detail to enable those skilled in the art to practice the teachings disclosed. Other examples may be used and derived therefrom, such that structural and logical substitutions and changes may be made without departing from the scope of this disclosure. The Detailed Description, therefore, is not to be taken in a limiting sense, and the scope of various examples is defined only by the appended claims, along with the full range of equivalents to which such claims are entitled.

Additionally, as used in this disclosure, phrases of the form “at least one of an A, a B, or a C,” “at least one of A, B, and C,” and the like should be interpreted to select at least one from the group that comprises “A, B, and C.” Unless explicitly stated otherwise in connection with a particular instance, in this disclosure, this manner of phrasing does not mean “at least one of A, at least one of B, and at least one of C.” As used in this disclosure, the example “at least one of an A, a B, or a C” would cover any of the following selections: {A}, {B}, {C}, {A, B}, {A, C}, {B, C}, and {A, B, C}.

Moreover, plural instances may be provided for resources, operations, or structures described herein as a single instance. Additionally, boundaries between various resources, operations, modules, engines, and data stores are somewhat arbitrary, and particular operations are illustrated in the context of specific illustrative configurations. Other allocations of functionality are envisioned and may fall within the scope of various examples of the present disclosure. In general, structures and functionality are presented as separate resources in the example; configurations may be implemented as a combined structure or resource. Similarly, structures and functionality presented as a single resource may be implemented as separate resources. These and other variations, modifications, additions, and improvements fall within a scope of examples of the present disclosure as represented by the appended claims. Accordingly, the specification and drawings are to be regarded in an illustrative rather than a restrictive sense.

What is claimed is:

1. A computer-implemented method comprising:
configuring a bridge for a drone simulation utilizing a drone simulator (DS) and a universal simulator (US), the DS being a custom simulator for the drone, the US being a generic simulator that provides at least one feature unavailable in the DS;
intermittently during the simulation:
obtaining a location and an orientation of the drone from the DS; and
sending the location and the orientation of the drone to the US; and
during the simulation:
receiving a DS request from the DS;
preparing a US request for the US in response to the DS request; and
sending the US request to the US.

2. The method as recited in claim 1, further comprising:
receiving a response to the US command; and
sending information about the response to the DS.

3. The method as recited in claim 1, wherein the US performs the simulation with physics disabled and the US updates the location of the drone based on the intermittently received location and orientation of the drone.

4. The method as recited in claim 1, wherein the DS provides a same interface as an interface provided by a real drone, wherein a control program is tested by interfacing with the DS utilizing same commands to be used with the real drone when the real drone is controlled by the control program.

5. The method as recited in claim 4, further comprising:
receiving, by the DS, a command from the control program; and
updating the simulation in the DS based on the command from the control program, wherein the bridge updates the location and the orientation of the drone in the US based on changes to the location and the orientation of the drone in the DS.

6. The method as recited in claim 1, wherein the location of the drone is received as a global positioning system (GPS) location from the DS, wherein sending the location and the orientation of the drone to the US further comprises:
translating the GPS location to coordinates for a three-dimensional space with origin in a home location of the drone; and
sending the coordinates to the US.

7. The method as recited in claim 1, wherein the drone is configured to provide a Robot Operating System (ROS) interface, wherein the US provides sensor information via the ROS that is accessible by the bridge and the DS.

8. The method as recited in claim 1, wherein the simulation is for manual flying of the drone based on manual flight commands for the drone, wherein the DS processes the manual flight commands to update the location and the orientation of the drone.

9. The method as recited in claim 1, wherein the US is configurable to include buildings and bridges in the simulation, wherein the DS is not configurable to include buildings and bridges in the simulation.

10. The method as recited in claim 1, wherein sending the location and the orientation of the drone to the US comprises:
sending the location of the drone, the orientation of the drone, and a gimbal orientation of the drone to the US.

11. A system comprising:
a memory comprising instructions; and
one or more computer processors, wherein the instructions, when executed by the one or more computer processors, cause the system to perform operations comprising:
configuring a bridge for a drone simulation utilizing a drone simulator (DS) and a universal simulator (US), the DS being a custom simulator for the drone, the US being a generic simulator that provides at least one feature unavailable in the DS;
intermittently during the simulation:
obtaining a location and an orientation of the drone from the DS; and
sending the location and the orientation of the drone to the US; and
during the simulation:
receiving a DS request from the DS;
preparing a US request for the US in response to the DS request; and
sending the US request to the US.

12. The system as recited in claim 11, wherein the instructions further cause the one or more computer processors to perform operations comprising:
receiving a response to the US command; and
sending information about the response to the DS.

13. The system as recited in claim 11, wherein the US performs the simulation with physics disabled and the US updates the location of the drone based on the intermittently received location and orientation of the drone.

14. The system as recited in claim 11, wherein the DS provides a same interface as an interface provided by a real drone, wherein a control program is tested by interfacing with the DS utilizing same commands to be used with the real drone when the real drone is controlled by the control program.

15. The system as recited in claim 14, wherein the instructions further cause the one or more computer processors to perform operations comprising:
receiving, by the DS, a command from the control program; and
updating the simulation in the DS based on the command from the control program, wherein the bridge updates the location and the orientation of the drone in the US based on changes to the location and the orientation of the drone in the DS.

16. A non-transitory machine-readable storage medium including instructions that, when executed by a machine, cause the machine to perform operations comprising:
configuring a bridge for a drone simulation utilizing a drone simulator (DS) and a universal simulator (US), the DS being a custom simulator for the drone, the US being a generic simulator that provides at least one feature unavailable in the DS;
intermittently during the simulation:
obtaining a location and an orientation of the drone from the DS; and
sending the location and the orientation of the drone to the US; and
during the simulation:
receiving a DS request from the DS;
preparing a US request for the US in response to the DS request; and
sending the US request to the US.

17. The non-transitory machine-readable storage medium as recited in claim 16, wherein the machine further performs operations comprising:
receiving a response to the US command; and
sending information about the response to the DS.

18. The non-transitory machine-readable storage medium as recited in claim 16, wherein the US performs the simulation with physics disabled and the US updates the location of the drone based on the intermittently received location and orientation of the drone.

19. The non-transitory machine-readable storage medium as recited in claim 16, wherein the DS provides a same interface as an interface provided by a real drone, wherein a control program is tested by interfacing with the DS utilizing same commands to be used with the real drone when the real drone is controlled by the control program.

20. The non-transitory machine-readable storage medium as recited in claim 19, wherein the machine further performs operations comprising:
receiving, by the DS, a command from the control program; and
updating the simulation in the DS based on the command from the control program, wherein the bridge updates the location and the orientation of the drone in the US based on changes to the location and the orientation of the drone in the DS.
